(19) United States
(12) Patent Application Publication
(10) Pub. No.: US 2024/0142122 A1
(43) Pub. Date: May 2, 2024

(54) COOLING SYSTEM AND COOLING METHOD

(71) Applicant: NEC Corporation, Minato-ku, Tokyo (JP)

(72) Inventors: Yoshinori MIYAMOTO, Tokyo (JP); Minoru YOSHIKAWA, Tokyo (JP); Koichi TODOROKI, Tokyo (JP)

(73) Assignee: NEC Corporation, Minato-ku, Tokyo (JP)

(21) Appl. No.: 18/279,705

(22) PCT Filed: Mar. 2, 2022
(86) PCT No.: PCT/JP2022/008986

§ 371 Date: Aug. 31, 2023

(30) Foreign Application Priority Data
Mar. 12, 2021 (JP) 2021-039893

(51) Int. Cl. F24F 7/06; F24F 13/10

(52) U.S. Cl. CPC F24F 7/06; F24F 13/10; F24F 2110/10

(57) ABSTRACT

The cooling system includes a duct that draws in air that is drawn in from an intake side of a cooling target, which is disposed in a room adjusted to a predetermined temperature, that absorbs the heat of the cooling target, and that is exhausted from an exhaust side of the cooling target, and that guides the air to the intake side; a cooler that is provided in the duct and that cools the air; a monitoring device that monitors a cooling state of at least one of the cooling target and the cooler; and a duct adjustment device that operates the duct to guide the air in the duct in a direction different from a direction toward the intake side when the monitoring device detects an abnormality in the cooling state.

### TECHNICAL FIELD

The present invention relates to a cooling system and a cooling method.

### BACKGROUND ART

Conventionally, in a data center provided with a plurality of servers, the server room where the servers are installed is maintained at an appropriate temperature by an air conditioning system. Furthermore, cooling air is supplied to each of the multiple servers mounted in a single rack by a local air conditioning system independent of the server room air conditioning system, thereby maintaining the operating environment of each server within a predetermined range.

The air conditioning system in the server room is required to ensure continuous operation of the air conditioning system to accommodate the continuous operation of the servers. In response to this need, the air conditioning capacity required for the entire server room is not satisfied by the sum of the individual rated capacities of the multiple air conditioning units (N units), but rather by providing redundancy by preparing (N+1) air conditioning units in case any one of the air conditioning units fails.

In contrast, local air conditioning is performed on multiple server units stacked in the same rack. Therefore, it is inevitable that the failure of one local air conditioning unit will reduce the cooling capacity for all of the multiple servers mounted in the same rack that are cooled by that air conditioning unit.

Technology related to air conditioning systems for server rooms and to local air conditioning systems are disclosed in Patent Document 1.

The device in Patent Document 1, upon detecting a decrease in the cooling capacity of a local air conditioning unit, operates a damper of a duct that supplies air from the local cooler to the cold aisle and a blower that supplies air to the server to prevent air that was not cooled due to a malfunction of the local air conditioning unit from being supplied to the server.

### PRIOR ART DOCUMENTS

### Patent Documents

Patent Document 1: Japanese Unexamined Patent Application, First Publication No. 2014-142106

### SUMMARY OF THE DISCLOSURE

### Problems to be Solved by the Disclosure

However, it is difficult to maintain a server at its operational temperature in Patent Document 1 because measures are merely taken to suppress the supply of hot air due to a malfunction of the local air conditioning system. As a result, processing capacity may have to be curtailed until the local air conditioning system is restored, or the server may have to be shut down.

An example of an example object of the present invention is to suppress a functional degradation in the cooling capacity of a server due to reduced cooling capacity or failure of a local air conditioning unit.

### Means for Solving the Problem

A cooling system according to the first example aspect includes: a duct that draws in air that is drawn in from an intake side of a cooling target, which is disposed in a room adjusted to a predetermined temperature, that absorbs the heat of the cooling target, and that is exhausted from an exhaust side of the cooling target, and that guides the air to the intake side; a cooler that is provided in the duct and that cools the air; a monitoring device that monitors a cooling state of at least one of the cooling target and the cooler; and a duct adjustment device that operates the duct to guide the air in the duct in a direction different from a direction toward the intake side when the monitoring device detects an abnormality in the cooling state.

A cooling method according to the second example aspect includes: drawing in air that is drawn in from an intake side of a cooling target, which is disposed in a room adjusted to a predetermined temperature, that absorbs the heat of the cooling target, and is exhausted from an exhaust side of the cooling target, cooling the air and guiding the air to the intake side; monitoring a cooling state of the cooling target; and guiding the air in a direction different from a direction toward the intake side when an abnormality in the cooling state is detected.

### Effect of Disclosure

According to the example embodiment of the present invention, it is possible to suppress the functional degradation of a server due to reduced cooling capacity of a local cooling device.

### BRIEF DESCRIPTION OF THE DRAWINGS

FIG. 1 is a cross-sectional view of a cooling system for an example configuration of the example embodiment of the present invention.

FIG. 2 is a perspective view of an overall schematic of the first example embodiment of the present invention.

FIG. 3 is a cross-sectional view of the cooling device according to the first example embodiment.

FIG. 4 is a piping diagram of the system supplying refrigerant to the cooling device in FIG. 3.

FIG. 5 is a block diagram of a local cooling system to which the first example embodiment is applied.

FIG. 6 is a flowchart of the control operation of the local cooling system.

FIG. 7A is an illustration of the operation of the device in FIG. 3.

FIG. 7B is an illustration of the operation of the device in FIG. 3.

FIG. 8 is a cross-sectional view of the cooling device according to the second example embodiment of the present invention.

FIG. 9 is a cross-sectional view of a server room equipped with the cooling system according to the third example embodiment of the present invention.

FIG. 10 is a perspective view of the outside air intake of the server room according to the third example embodiment.

### EXAMPLE EMBODIMENT

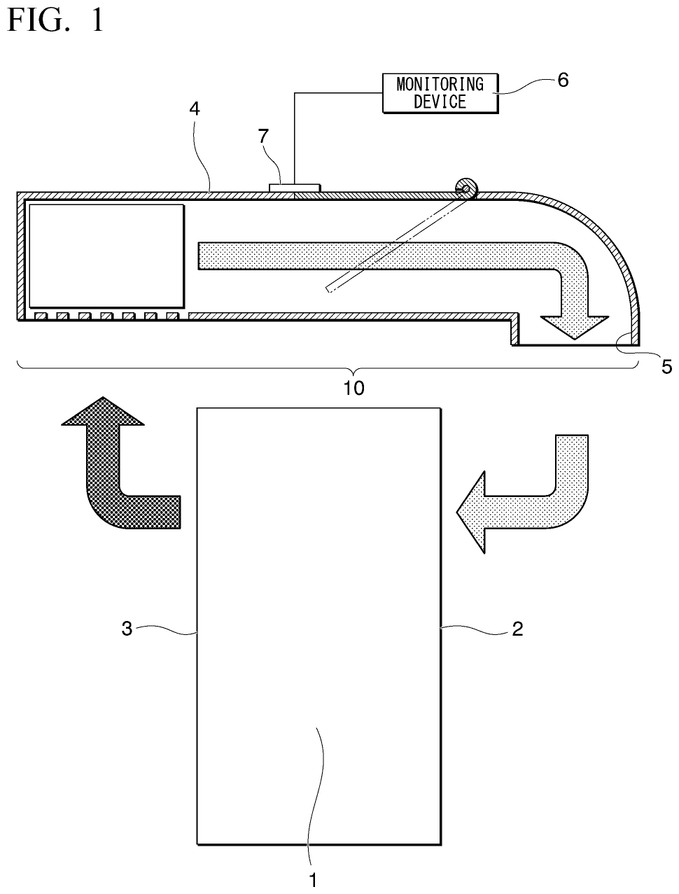

An example configuration of an example embodiment of the invention will be described with reference to FIG. 1.

A cooling system is provided with a duct 4, a cooling device 10, a monitoring device 6, and a duct adjustment device 7. The duct 4 draws in air that has been drawn in from an intake side 2 of a cooling target 1, which is disposed in a room adjusted to a predetermined temperature, the air absorbing heat from the cooling target 1 and being exhausted from an exhaust side 3. The cooling device 10 cools the air upstream of an outlet 5 of the duct 4 and guides the air to the exhaust side 3. The monitoring device 6 monitors the cooling state of at least one of the cooling target 1 and the cooling device 10. The duct adjustment device 7 operates the cooling device 10 to switch the air outlet of the duct 4 to a side other than the intake side 2 when the monitoring device 6 has detected an abnormality in the cooling state.

According to the above configuration, air that has absorbed heat in the cooling target 1 and had been discharged from the exhaust side 3 rises as its temperature rises, is sucked into the duct 4 of the cooling device 10, cooled, and then discharged from the outlet 5. When the cooling device 10 is cooling air normally, the cold air, whose density has increased due to the cooling, descends downward, is sucked into the cooling target 1 from the intake side 2, absorbs the heat generated inside the cooling target 1, and is then exhausted the exhaust side 3.

For example, if the monitoring device 6 detects an abnormality in the cooling state, such as a failure of the compressor that supplies refrigerant to the cooler, the duct adjustment device 7 operates the cooling device 10 to guide the air discharged from the exhaust side 3 to other than the intake side 2. This prevents the phenomenon in which air heated to a high temperature by absorbing the heat inside the cooling target 1 is sucked into the cooling target 1 again from the intake side 2.

The cooling method according to the configuration of the example embodiment of the present invention has a step of drawing in air that was drawn in from the intake side 2 of the cooling target 1, which is disposed in a room adjusted to a predetermined temperature, that absorbs the heat in the cooling target 1 and is exhausted from the exhaust side 3, cooling the air and guiding the air to the intake side 2; a step of monitoring the cooling state of the cooling target 1; and a step of switching the flow of the air guided from the exhaust side 3 to the intake side 2 in a direction that leads to other than the intake side 2 when an abnormality in the cooling state is detected.

According to the above configuration, the phenomenon in which air that has absorbed heat in the cooling target 1 is sucked into the cooling target again from the intake side 2 without being cooled can be prevented.

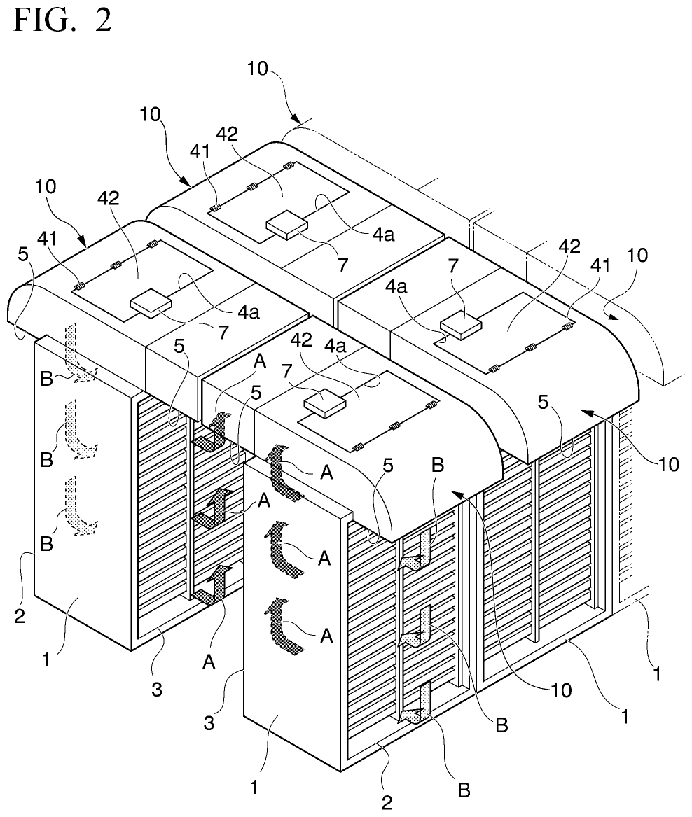

FIGS. 2 through 6 illustrate the first example embodiment of the invention. In FIGS. 2 through 6, the same reference numerals are used for constitutions common to FIG. 1 to simplify the explanation.

FIG. 2 shows an example of a server room equipped with the cooling system of the first example embodiment.

In this server room, a plurality of cooling targets 1 are installed. The plurality of cooling targets 1 are for example electronic devices such as data servers, and are arranged vertically in a frame or box-shaped enclosure.

The cooling device 10 is located above the cooling target 1, guides the air drawn in from the inlet of the duct 4 as shown by arrows A to the outlet 5, and releases the air downward as shown by arrows B.

Part of the top surface of the duct 4 can be opened and closed by a plate-shaped damper 42 that is rotatable around a central axis 41. The opening and closing of the duct 4 is operated by the duct adjustment device 7.

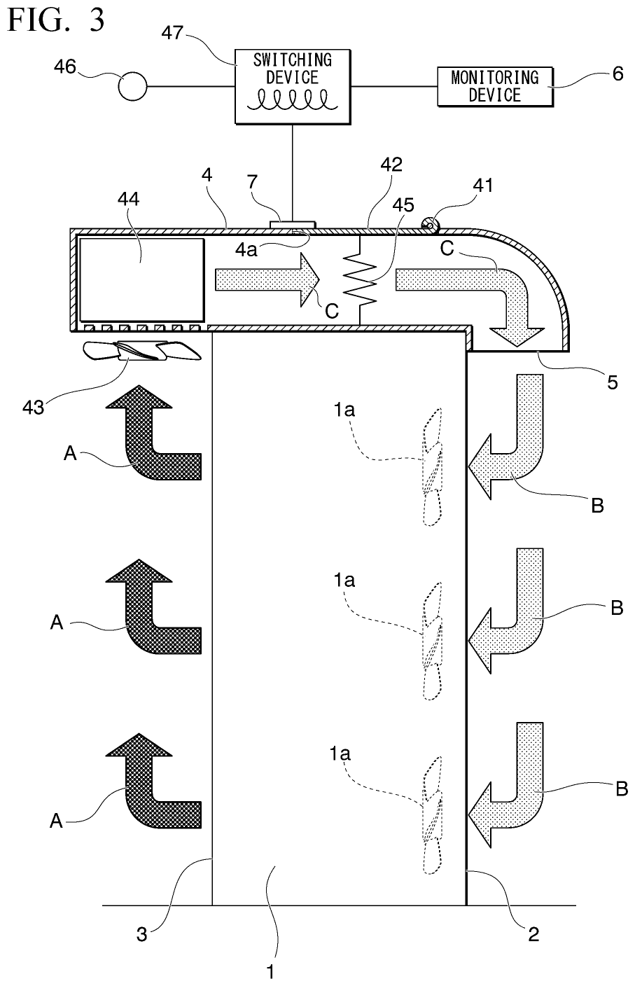

FIG. 3 shows a longitudinal section of one cooling device 10 in the server room shown in FIG. 2.

The cooling target 1, for example, consists of computers (not shown) functioning as servers are stored in racks over multiple levels. The computer of each level is equipped with a fan 1a that distributes air from the intake side 2 to the exhaust side 3. In FIG. 3, three fans 1a are shown for convenience. The number of the fans 1a is adjusted according to the number of servers. The air flowing inside the cooling target 1 absorbs the heat generated by the heat generating elements, etc. inside the cooling target 1 and is released, with the air expanding by the absorption of the heat in the cooling target 1, whereby the air rises as shown by the arrows A in FIG. 3.

A fan 43 is provided at the inlet of the duct 4. This fan 43 draws the air rising in the direction of the arrows A into the duct 4. The shape of the fan 43 corresponds to the cross-sectional shape of the duct 4. The fan 43 has a turning radius corresponding to the short-side dimension in the cross-section of the duct 4, which is rectangular in shape. The fans 43 are arranged in a number corresponding to the long-side dimension in the cross-section of the duct 4.

The duct 4 has a cooler 44 that cools the intake air by heat exchange with a refrigerant at a position above the fan 43. The duct 4 guides the intake air cooled by this cooler 44 in the direction of arrow C and sends it downward from the outlet 5.

The duct adjustment device 7 is located in the middle of the duct 4. The duct adjustment device 7, by opening and closing the duct 4 by means of the damper 42, exhausts the air flowing through the duct 4 into the server room. The inside of the server room is maintained at a predetermined temperature by an air conditioning system (not shown). In general, the area where air discharged from the cooling target 1 flows as shown by the arrows A is called the hot aisle, while the area where air is sucked into the cooling target 1 as shown by the arrows B is called the cold aisle.

An opening 4a is formed in the upper surface of the duct 4 at a position downstream from the cooler 44. The duct adjustment device 7 controls the opening and closing of the damper 42. The damper 42 has a plate shape that corresponds to the opening 4a. In other words, the damper 42 is biased counterclockwise in FIG. 3 around the central axis 41 by a tension spring 45. The damper 42 thus biased is supported by the duct adjustment device 7 in a position that closes the opening 4a. By releasing the support of the damper 42 by the duct adjustment device 7, the contraction of the tension spring 45 causes the damper 42 to rotate counterclockwise in FIG. 3. As a result, the damper 42 can traverse the duct 4 to suppress the flow of air in the duct 4. Moreover, the damper 42 can be rotated to a position that guides air to above the duct 4, i.e., upward into the server room.

A switching device 47 provided between the monitoring device 6 and a power supply 46 is operated by a signal supplied from the monitoring device 6. The operation of the switching device 47 connects the duct adjustment device 7 to the power supply 46 or shuts off the supply of power to the duct adjustment device 7.

The switching device 47 in the first example embodiment is a relay device that opens and closes contacts by magnetic force. From a fail-safe standpoint, a normally open contact is used in which the duct adjustment device 7 is connected to the power supply 46 when in an energized state. In other words, when the power supply 46 goes down, or when an operation signal is supplied from the monitoring device 6, the power supply to the duct adjustment device 7 is cut off and the damper 42 is configured to rotate counterclockwise to open the duct 4.

For example, if the duct adjustment device 7 is an electromagnet and the damper 42 is made of ferromagnetic zinc-coated steel sheet or the like, the duct adjustment device 7 in an energized state supports the damper 42 in a position to close the opening 4a in FIG. 3 against the pulling force of the tension spring 45. If the damper 42 is not composed of a ferromagnetic material such as steel plate, a ferromagnetic piece can be provided to attract the damper 42 by magnetic force, and the magnetic force of the duct adjustment device 7 can be applied to this ferromagnetic piece.

As the duct adjustment device 7, instead of an electromagnet, a constitution may be adopted that brings a plunger (not shown) driven by a voice coil or the like into contact with a part of the damper 42 to support it in the closed position, and allows rotation of the damper 42 by contraction of the tension spring 45 due to withdrawal of the plunger.

The damper 42 can be rotated clockwise in FIG. 3 to return the opening 4a to the closed position by manual operation or by activating an electric motor or pneumatic cylinder under predetermined conditions.

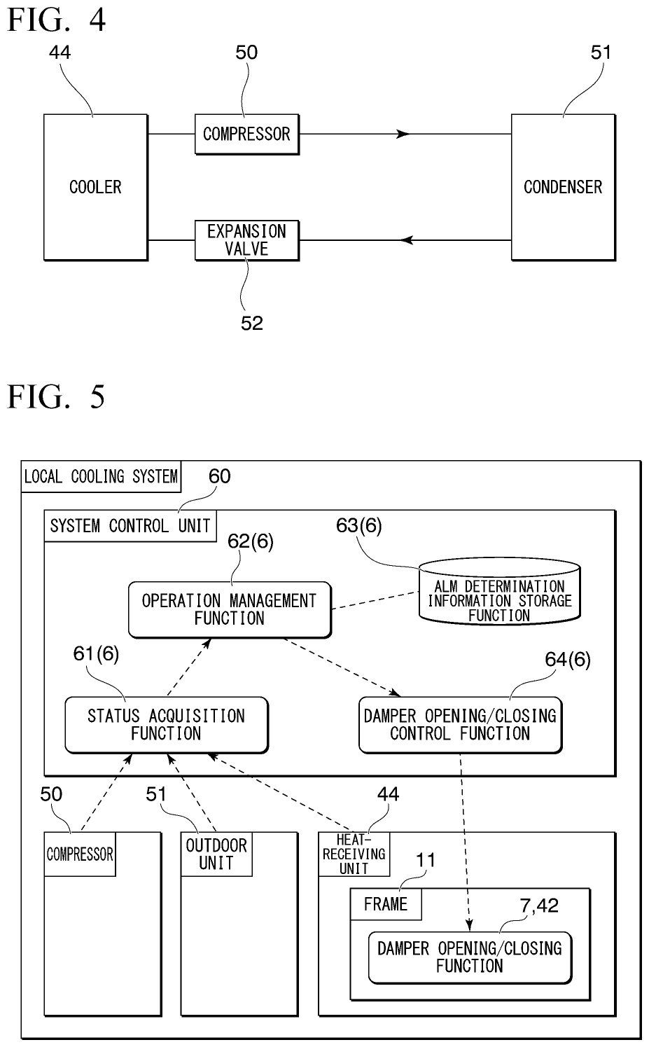

Referring to FIGS. 4 and 5, the overall configuration of the system supplying refrigerant to the cooler 44 and the local cooling system will be explained.

The refrigerant exchanges heat with the air in the server room by the cooler 44. The refrigerant is then compressed by the compressor 50. The refrigerant is then condensed and dissipates heat into the atmosphere through the condenser 51. The refrigerant then circulates through an expansion valve 52 to the cooler 44 again. The refrigerant, which has dissipated heat through heat exchange in the condenser 51, is depressurized by undergoing a predetermined pressure loss by adjusting the opening of the expansion valve 52, becoming a low-temperature gas-liquid mixture state, which is then supplied to the cooler 44. The cooler 44, for example, consists of a refrigerant tube through which the refrigerant flows and a heat sink for heat exchange with the air.

The cooling system in the first example embodiment is controlled by the system control unit 60 shown in FIG. 5.

The monitoring device 6 has a status acquisition function 61, an operation management function 62, an ALM (alarm) determination information storage function 63, and a damper opening/closing control function 64. The operational status of a compression unit corresponding to the compressor 50, an outdoor unit corresponding to the condenser 51, and a heat-receiving unit corresponding to the cooler 44 are measured by various sensors and supplied to the status acquisition function 61. The status acquisition function 61 supplies the acquired data on the operational status to the operation management function 62. This operation management function 62 refers to the data necessary for operation and control of the cooling system stored in the ALM determination information storage function 63, and supplies a signal to the damper opening/closing control function 64 to order opening and closing. This damper opening/closing control function 64 can control the opening and closing of the damper 42 via the duct adjustment device 7 for each single cooling target 1 mounted in a frame 11.

The ALM determination information storage function 63 stores the ALM information necessary to determine whether or not a situation has occurred that should trigger an alarm in the operation and management of the local cooling system. The ALM determination information storage function 63 stores, as the ALM information, for example, information that associates measured data such as temperature, communication status, etc. of components with causes of failure. The damper opening/closing control function 64 operates the damper 42 in the event of a local cooling system failure by operating the duct adjustment device 7 as a damper opening/closing function.

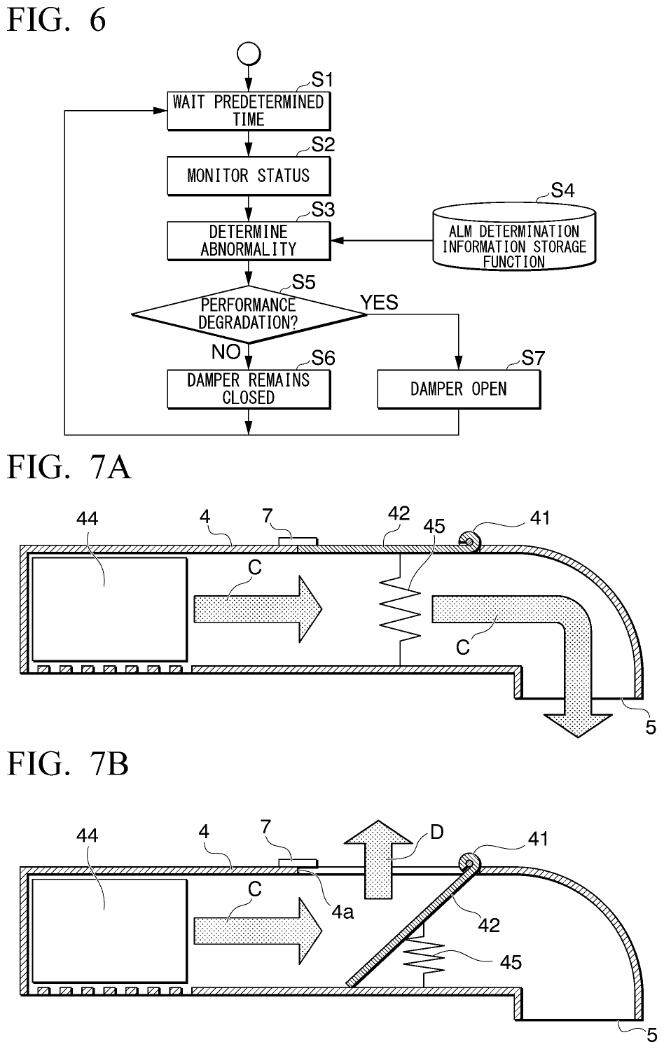

Referring to FIGS. 6, 7A and 7B, each step S1-S7 of the damper opening/closing control performed by the system control unit 60 of the first example embodiment will be described.

(Step S1) The system control unit 60 waits to execute the damper opening/closing control until a predetermined period of time has elapsed. In this state, the duct adjustment device 7 closes the opening 4a of the duct 4 by holding the damper 42 in the raised position, as shown in FIG. 7A. The tension spring 45 also exerts a counterclockwise force on the damper 42 about the central axis 41.

(Step S2) The system control unit 60 starts monitoring the operational status of the cooling system and collects measurement data from various sensors and other sources using the status acquisition function 61.

(Steps S3 and S4) The system control unit 60 determines whether or not there is an abnormality based on the collected measurement data and the data in the ALM determination information storage function 63. The system control unit 60, for example, determines that there is an abnormality when the temperature of a certain part of the cooling target 1, such as a server, exceeds a threshold value in light of past data, the current processing load, and other data. As another example, the system control unit 60 determines that there is an abnormality if the load current of the electric motor (not shown) driving the compressor 50 exceeds a threshold value or if the load current cannot be detected.

(Step S5) The system control unit 60, upon determining that the cooling device 10 is performing at its normal cooling capacity, proceeds to Step S6. If the system control unit 60 determines that the cooling device 10 is not performing at its normal cooling capacity, it proceeds to Step S7.

(Step S6) If local cooling is determined to be normal, the damper 42 shown in FIG. 7A remains closed.

(Step S7) If it is determined that local cooling is not normally taking place, as shown in FIG. 7B, the fixation of the damper 42 by the duct adjustment device 7 is released, and the contraction of the tension spring 45 causes the damper 42 to rotate counterclockwise around the central axis 41 to open the opening 4a. As a result, air that had been flowing in the duct 4 as shown by the arrow C flows upward through opening 4a as shown by the arrow D. Here, the plate that constitutes the damper 42 is in an inclined state, as shown in FIG. 7B, and also serves as a guide plate that guides the air flowing in the duct 4 upward.

In other words, air flowing through the duct 4 with no or insufficient cooling by the cooler 44 (exhaust air discharged and rising as indicated by the arrows A in FIG. 3, etc.) is discharged to the upper part of the server room. As a result, the air being immediately sucked into the cooling target as indicated by the arrows B in FIG. 3 is suppressed. In other words, the fan 1a of the cooling target 1 can draw in air from the air-conditioned server room (at least air that is cooler than the exhaust air indicated by the arrows A, since the server room is maintained at a predetermined temperature by the air conditioning system).

In Step S7, in addition to the process of opening the damper 42, the fan 43 may be rotated at the upper limit of its rated speed to promote suction into the duct 4 of the exhaust air rising up the exhaust side 3 of the cooling target 1, as well as the exhaust from the opening 4a.

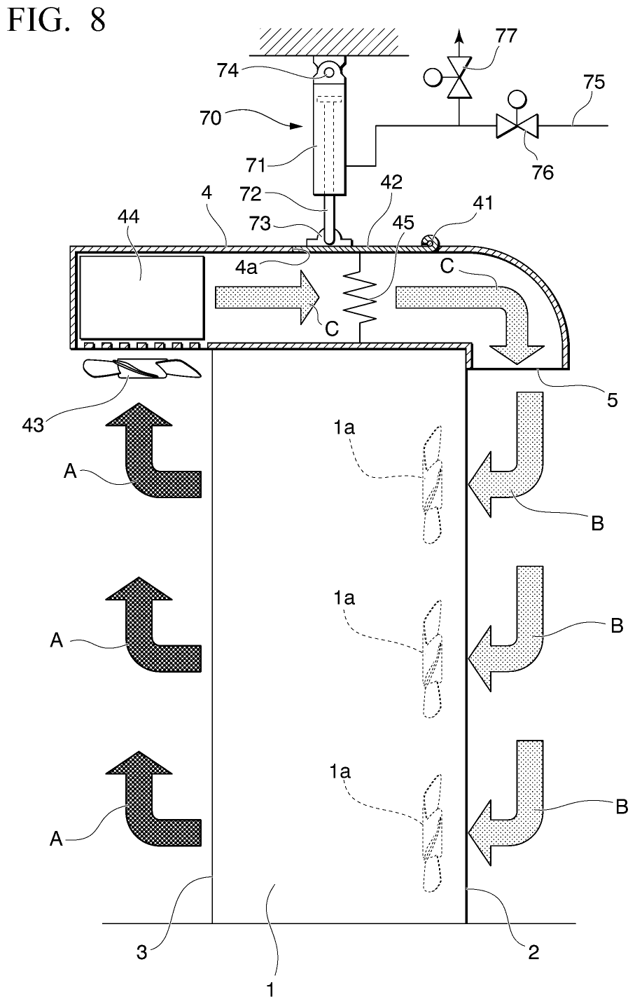

FIG. 8 illustrates the second example embodiment of the present invention. In FIG. 8, common components with FIGS. 1 to 7B are labeled with the same reference numbers to simplify the explanation.

The damper 42, shown in FIG. 8, is operated by an air cylinder 70 to open and close the duct 4. A piston 72 is freely movable back and forth in a cylinder 71 of the air cylinder 70. One end of the piston 72 is rotatably connected to the damper 42 with a pin 73. One end of the cylinder 71 is coupled in a freely rotatable manner about a pin 74 to a support such as a beam that constitutes the server room, for example.

Compressed air is supplied to the space on one side of the piston 72 (the side that retracts the piston 72 in FIG. 8) in the cylinder 71 via air piping 75. The air piping 75 has a solenoid valve 76 connected to a compressed air source 75 and a solenoid valve 77 that can release the compressed air to the atmosphere.

By opening the solenoid valve 76 and closing the solenoid valve 77, compressed air can be supplied to move the piston 72 in a direction that draws it into cylinder 71. As a result, the damper 42 can be rotated clockwise in FIG. 8. Furthermore, by closing the solenoid valves 76 and 77 in the state of the damper having closed the opening 4a as shown in FIG. 8, it is possible to maintain the closed state of the opening 4a. In this state, the cooler 44 can cool the air exhausted from the exhaust side 3 of the cooling target 1 and supply it to the intake side 2.

In the above second example embodiment, by controlling the opening and closing of the solenoid valves 76 and 77 with a monitoring device, it is possible to guide the air exhausted from the exhaust side 3 in a direction different from that toward the intake side 2 when the cooler 44 capacity is reduced or stopped.

When the cooling capacity by the cooler 44 decreases or the cooler 44 stops, the solenoid valve 77 is opened, whereby the compressed air in the cylinder 71 is released into the atmosphere and the piston 72 is pulled out of the cylinder 71. As the piston 72 is pulled out, the tension spring 45 contracts. The force acting on damper 42 as the tension spring 45 contracts causes the damper 42 to rotate counterclockwise in FIG. 8 to open the opening 4a. In other words, air in the duct can be released in the direction of the arrow D, as shown in FIG. 7B in the first example embodiment.

In the operation to open the solenoid valve 77, it is desirable that the solenoid valve 76 be closed. However, if, for example, the bore diameter of the solenoid valve 76 is sufficiently smaller than that of the solenoid valve 77, the pressure in the cylinder 71 can be reduced to rotate the damper 42 even if solenoid valve 76 remains open.

The case shall be described in which, after compressed air in the cylinder 71 is released to open the damper 42 upon detection of an abnormality, the cooler 44 is restored and cooling is enabled. In this case, the solenoid valve 76 is opened to introduce compressed air into the cylinder 71 while the solenoid valve 77 is closed. In other words, compressed air is introduced into the cylinder 71. As a result, the damper 42 is rotated clockwise and raised to close the opening 4a, as shown in FIG. 8. Closing the solenoid valve 76 with the opening 4a closed places the damper 42 in a standby state for opening in the event of an abnormality.

From a fail-safe standpoint, the solenoid valve 77 should have an operating characteristic of being maintained in a closed state when power is supplied and opened when power is cut off. The solenoid valve 76 can achieve the initial purpose of opening the damper 42 in the event of an abnormality, whether the operating characteristic thereof is being maintained closed by the power supply and opened when power is cut off, as with the solenoid valve 77, or vice versa.

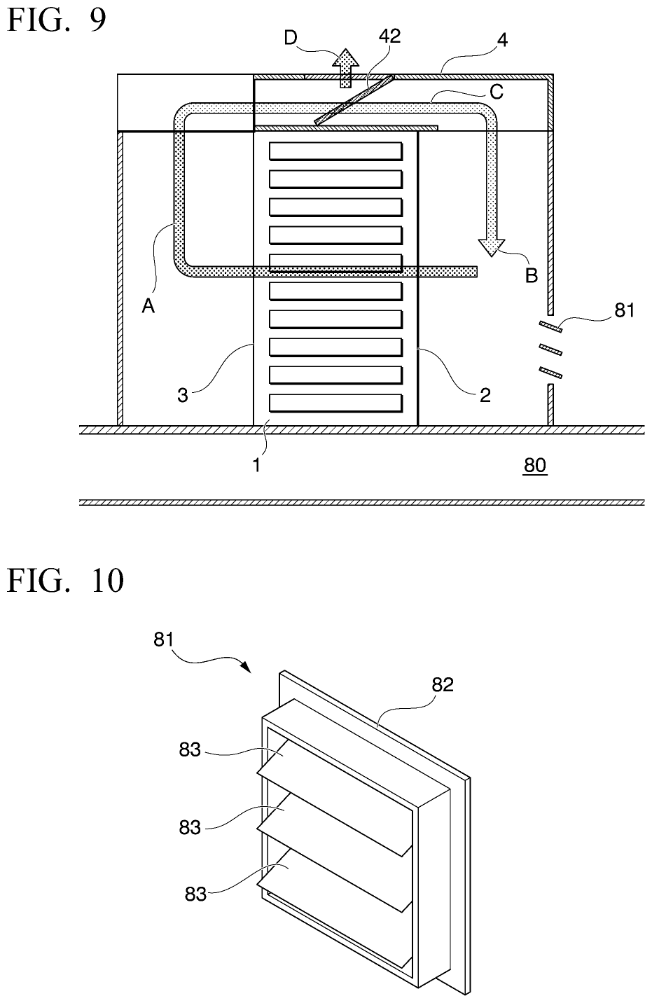

FIGS. 9 and 10 illustrate the third example embodiment of the invention. In FIGS. 9 and 10, common components with FIGS. 1 to 8 are labeled with the same reference numbers to simplify the explanation.

This server room has an underfloor space 80, and under normal cooling conditions, cooling is performed by circulating air along the paths of arrow A, arrow C, and arrow B (arrow A, arrow C, and arrow B are connected in FIG. 9). If there is an abnormality in the cooling process, the air in the duct 4 can escape in the direction of arrow D. The server room, which is maintained at a predetermined temperature by the air conditioning system, can also draw in outside air through a server room ventilation opening 81.

The server room ventilation opening 81 has a frame 82 and a plurality of shutter plates 83 provided inside the frame 82, as shown in FIG. 10. The plurality of shutter plates 83 are each rotatable around a horizontal axis. The server room ventilation opening 81 is closed by orienting the shutter plates 83 vertically. By orienting the shutter plates 83 horizontally, the server room ventilation opening 81 can be opened to introduce outside air.

In other words, the air conditioning system in the server room minimizes the intake of outside air to minimize the influence of the outside temperature. However, if, for example, high-temperature air is released from the duct 4 into the server room due to a malfunction of the local cooling device 10 and the server room becomes hotter than the outside temperature, by driving the shafts of the shutter plates 83 with, for example, an electric motor or the like to make the shutter plates 83 horizontally oriented, the server room ventilation opening 81 can be opened. Thus, by opening the server room ventilation opening 81 to introduce outside air, an excessive temperature rise in the server room caused by the opening of damper 42 can be suppressed.

The cooling target is not limited to a server in the implementation. The cooling system according to the example embodiment of the present invention can be used for cooling various heat-generating devices, such as power supplies and other electronic equipment.

The shape of the duct, the diameter and number of fans, and the driving mechanism of the damper are not limited to the above example embodiments.

While the above preferred example embodiments of the invention have been described in detail with reference to the drawings, specific configurations are not limited to these example embodiments, and also include design changes and the like to the extent that they do not depart from the gist of the invention.

Priority is claimed on Japanese Patent Application No. 2021-039893, filed on Mar. 12, 2021, the content of which is incorporated herein by reference.

### INDUSTRIAL APPLICABILITY

The present invention can be used for a cooling system and a cooling method.

### DESCRIPTION OF REFERENCE SIGNS

1 Cooling target
2 Intake side
3 Exhaust side
4 Duct
4a Opening
5 Outlet
6 Monitoring device
7 Duct adjustment device
10 (Local) Cooling device
11 Frame
41 Central axis
42 Damper
43 Fan
44 Cooler (heat-receiving unit)
45 Tension spring
46 Power supply
47 Switching device
50 Compressor
51 Condenser
52 Expansion valve
60 System control unit
61 Status acquisition function
62 Operation management function
63 ALM determination information storage function
64 Damper opening/closing control function
70 Air cylinder
71 Cylinder
72 Piston
73, 74 Pin
75 Air piping
76, 77 Solenoid valve
80 Underfloor space
81 Server room ventilation opening
82 Frame
83 Shutter plate

What is claimed is:

1. A cooling system comprising:
a duct that draws in air that is drawn in from an intake side of a cooling target, which is disposed in a room adjusted to a predetermined temperature, that absorbs the heat of the cooling target, and that is exhausted from an exhaust side of the cooling target, and that guides the air to the intake side;
a cooler that is provided in the duct and that cools the air;
a monitoring device that monitors a cooling state of at least one of the cooling target and the cooler; and
a duct adjustment device that operates the duct to guide the air in the duct in a direction different from a direction toward the intake side when the monitoring device detects an abnormality in the cooling state.

2. The cooling system according to claim 1, wherein the duct comprises a damper that guides the air in the duct to the outside of the duct and blocks the flow of the air to the intake side.

3. The cooling system according to claim 2, wherein the duct adjustment device operates the damper to guide the air out of the duct and shuts off the flow of the air to the intake side when the power supply to the duct adjustment device is cut off.

4. The cooling system according to claim 2, wherein the damper is subjected to an elastic force in the direction of opening the duct, and the duct adjustment device restrains the movement of the damper against the elastic force or releases the restraint of the damper's movement.

5. The cooling system according to claim 2, further comprising a fan that draws in air from the exhaust side into the duct,
wherein the duct adjustment device controls the fan so that a rotation speed after the abnormality is detected is greater than a rotation speed before the abnormality is detected.

6. The cooling system according to claim 2, further comprising an outside air intake adjustment device that adjusts the amount of outside air taken into the room adjusted to the predetermined temperature,
wherein the duct regulation device, when the abnormality is detected, increases the amount of outside air taken in by the outside air intake adjustment device compared to before the abnormality is detected.

7. A cooling method comprising:
drawing in air that is drawn in from an intake side of a cooling target, which is disposed in a room adjusted to a predetermined temperature, that absorbs the heat of the cooling target, and is exhausted from an exhaust side of the cooling target, cooling the air and guiding the air to the intake side;
monitoring a cooling state of the cooling target; and
guiding the air in a direction different from a direction toward the intake side when an abnormality in the cooling state is detected.
